(19) United States
(12) Patent Application Publication
(10) Pub. No.: US 2026/0155643 A1
(43) Pub. Date: Jun. 4, 2026

(54) SMART ELECTRONIC SWITCH

(71) Applicant: Infineon Technologies AG, Neubiberg (DE)

(72) Inventors: Sureshkumar RAMALINGAM, Villach (AT); Mirko BERNARDONI, Villach (AT); Christian DJELASSI-TSCHECK, Villach (AT); Robert ILLING, Finkenstein am Faaker See (AT)

(21) Appl. No.: 19/365,587

(22) Filed: Oct. 22, 2025

(30) Foreign Application Priority Data
Nov. 29, 2024 (DE) 102024135516.6

(51) Int. Cl. H02H 1/00; H02H 5/04; H03K 17/0812; H03K 17/18

(52) U.S. Cl. CPC H02H 1/0007; H02H 5/044; H03K 17/08122; H03K 17/18; H03K 2217/0027

(57) ABSTRACT

A circuit is described herein which may be used as an electronic fuse. According to one example, the circuit includes an integrated circuit (IC) with a chip contact for connecting, during operation, a filter circuit. The IC further includes a driver configured to drive a power transistor in accordance with a logic signal; a squaring circuit configured to receive a current sense signal that represents a load current passing through the power transistor and to output, at the chip contact, a first current that represents the squared load current; a comparator circuit configured to compare a voltage present at the chip contact with a reference voltage; and a control logic configured to generate the logic signal and to cause a switch-off of the power transistor dependent on an output signal of the comparator circuit.

### TECHNICAL FIELD

The present disclosure relates to the field of control / driver circuits for electronic switches such as metal-oxide-semiconductor (MOS) transistors or the like.

### BACKGROUND

Almost every electric installation (e.g. in an automobile, in a house, electric subsystems of larger installations) include one of more fuses to provide an over-current protection. Standard fuses include piece of wire, which provides a low-ohmic current path in case the current passing through the fuse is below a nominal current. However, the piece of wire is designed to heat up and melt or vaporize when the current passing through the fuse exceeds the nominal current for a specific time. Once triggered a fuse has to be replaced by a new one.

Fuses are increasingly replaced by circuit breakers. A circuit breaker is an automatically operated electrical switch designed to protect an electrical circuit from damage caused by overcurrent or overload or short-circuit. Circuit breakers may include electro-mechanical relays, which are triggered to disconnect the protected circuit from the supply when an over-current (i.e. a current exceeding the nominal current) is detected. In many applications (e.g. in the on-board power supply of an automobile), circuit breakers may be implemented using an electronic switch (e.g. a MOS transistor, an IGBT or the like) to disconnect the protected circuit or subsystem from the supply in case of an over-current. Such electronic circuit breakers may also be referred to as electronic fuses (e-fuses or smart fuses) or smart switches. Besides its function as a circuit breaker, an electronic fuse may also be used to regularly switch a load on and off. Usually, the switching state (on/off) of electronic switches such as MOS transistors is controlled using so-called driver circuits or simply drivers (gate drivers in case of MOS transistors).

However, at least in some electronic circuit breakers (electronic fuses or e-fuses) common driver circuits may be inadequate with regard to fault tolerance and functional safety, which may be an issue particularly in automotive applications, in which standards concerning functional safety must be complied with (e.g. ISO 26262). In fact, an electronic fuse needs more than just replacing a classical fuse by an electronic switch. A robust implementation of an electronic fuse entails various challenges. Further, current configurability of the e-fuse for different applications and use-cases may be an issue.

### SUMMARY

A circuit is described herein which may be used as an electronic fuse. According to one example, the circuit includes an integrated circuit (IC) with a chip contact for connecting, during operation, a filter circuit. The IC further includes a driver configured to drive a power transistor in accordance with a logic signal; a squaring circuit configured to receive a current sense signal that represents a load current passing through the power transistor and to output, at the chip contact, a first current that represents the squared load current; a comparator circuit configured to compare a voltage present at the chip contact with a reference voltage; and a control logic configured to generate the logic signal and to cause a switch-off of the power transistor dependent on an output signal of the comparator circuit.

### BRIEF DESCRIPTION OF THE DRAWINGS

The invention can be better understood with reference to the following drawings and descriptions. The components in the figures are not necessarily to scale; instead emphasis is placed upon illustrating the principles of the invention. Moreover, in the figures, like reference numerals designate corresponding parts. In the drawings:

FIG. 1 schematically illustrates one example of an electronic fuse circuit implemented with a smart switch and a microcontroller.

FIG. 2 illustrates one embodiment of a smart switch, which can be used in an electronic fuse circuit. The characteristic of the electronic fuse can be set via an externally connected filter circuit.

FIGS. 3 to 5 illustrate various embodiments which are modifications of the example of FIG. 2.

FIG. 6 illustrates a further embodiment which is also a modification of the example of FIG. 2 and does not require a digital bus interface.

FIG. 7 illustrates a further modification of FIG. 2.

### DETAILED DESCRIPTION

In the following detailed description, reference is made to the accompanying drawings. The drawings form a part of the description and, for the purpose of illustration, show examples of how the invention may be used and implemented. It is to be understood that the features of the various embodiments described herein may be combined with each other, unless specifically noted otherwise.

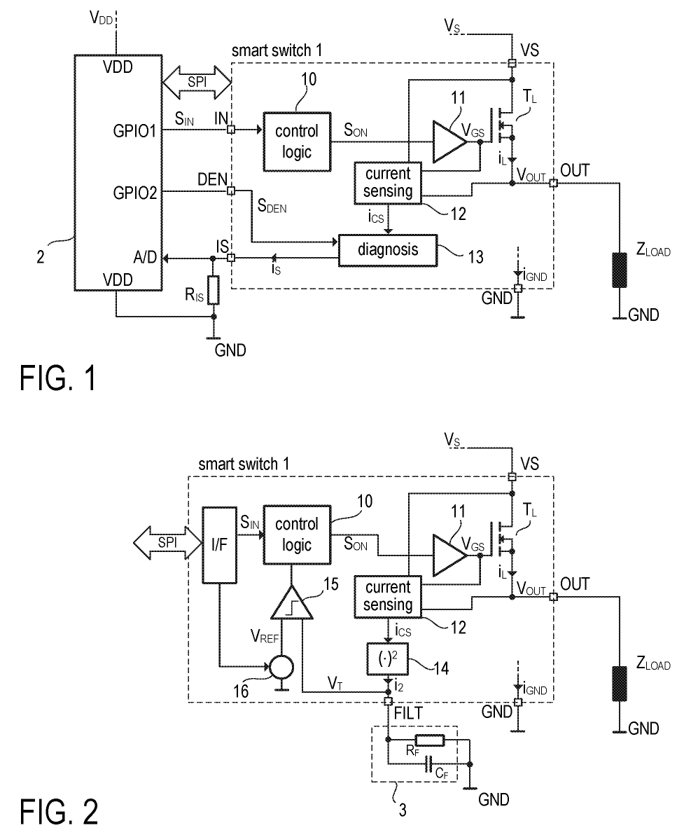

FIG. 1 illustrates one example of an electronic circuit which can be operated as an electronic fuse. The electronic circuit includes an integrated circuit (smart circuit 1) with an electronic switch T_{L} that may be a metal-oxide-semiconductor (MOS) field-effect transistor (FET), an insulated-gate bipolar transistor (IGBT) or any other type of transistor. The electronic switch T_{L} has a load current path connected between two circuit nodes, i.e. between a supply terminal VS and an output terminal OUT in the present example. The subsystem that is to be protected by the electronic fuse circuit is symbolized by the electronic load Z_{LOAD}. In the depicted example, the electronic switch T_{L} is an n-channel MOSFET in a high-side configuration (high-side switch). Accordingly, the drain electrode of the transistor T_{L} is connected to the supply terminal VS and the source terminal of the transistor T_{L} is connected to the output terminal OUT. When the transistor T_{L} is in an on-state, the supply voltage V_{S}, which is present at the supply terminal VS during operation, is applied to the load Z_{L}.

A gate driver 11 is used to drive the transistor T_{L} into an on-state or an off-state (i.e. to switch it on and off) in accordance with a logic signal S_{ON}. Suitable gate drivers are as such known and thus not discussed herein in more detail. The logic signal S_{ON} may be generated by a logic circuit labelled “control logic 10” in FIG. 1. The control logic 10 may be configured to output the logic signal S_{ON} with a specific logic level (e.g. a High level to switch the transistor T_{L} on and a Low level to switch it off). The control logic 10 may be further configured to generate the logic signal S_{ON} in response to the reception of a switching command, which may be received, for example, from an external controller circuit via a digital communication link. In one example, the external controller circuit is a microcontroller 2 that is capable of communicating with the smart switch 1 via a Serial Peripheral Interface (SPI) bus. In this example, the microcontroller 2 can send a digital switching command to the control logic 10 of the smart switch 1 in order to trigger a switch-on or switch-off of the transistor T_{L}. Additionally or alternatively, the logic level of an input signal S_{IN}, which is applied at an input pin IN of the smart switch 1, may be regarded as switching command. In this case, a High Level of the input signal may trigger a switch-on of the transistor T_{L} whereas a Low level may trigger a switch-off (or vice versa). It is understood that the logic circuit 10 may provide further functions dependent on the actual implementation of the smart switch 1. Such functions may include, amongst others an over-temperature protection, an under-voltage detection or the like.

The smart switch 1 also includes a current sensing circuit 12 which is coupled to the electronic switch T_{L} and configured to provide a current sense signal i_{CS} that represents the load current i_{L}. For example, the current sensing circuit 12 may include a so-called sense transistor that is coupled to the transistor T_{L} and operated (approximately) in the same operating point as the transistor T_{L} so that the current passing through the sense transistor is proportional to the load current i_{L}. The current passing through the sense transistor may be used as current sense signal i_{CS}. Sense transistors for measuring the load current of a (power) transistor is as such known and therefore not explained herein in more detail. It is understood that other current sensing concepts may be used. In a simple example, the current sensing circuit 12 includes a low-ohmic sense resistor coupled between the transistor T_{L} and the output terminal OUT. In this case, the voltage drop across the sense resistor may be used to generate a current sense signal.

According to the depicted example, the smart switch 1 includes a diagnosis circuit 13, which is configured to output, upon request, diagnosis information concerning the operation of the smart switch 1. In the present example, the diagnosis circuit 13 is configured to output a diagnosis current i_{S} at the terminal IS upon receiving a diagnosis request. The diagnosis request may be indicated to the diagnosis circuit 13 by a specific logic level of an enable signal S_{DEN} (diagnosis enable signal) applied to a diagnosis terminal DEN. In the present example, the microcontroller 2 may output the signal S_{DEN} with a High level to cause the diagnosis circuit 13 to output a diagnosis current i_{S} at the terminal IS which is equal to (or indicative of) the current sense signal i_{CS}.

In the depicted example, the diagnosis current i_{S} is drained via a resistor R_{IS}, which is connected between the terminal IS of the smart switch 1 and ground. The voltage drop V_{IS} across the resistor equals R_{IS}⋅i_{S}, and this voltage may be supplied to an analog input of the microcontroller 2. This allows the microcontroller 2 to obtain information concerning the load current i_{L} and to control the operation of the smart switch 1 dependent on the load current i_{L}. For example, the microcontroller 2 may monitor the load current i_{L} by regularly requesting diagnosis information from the smart switch 1 and to trigger a switch-off of the transistor T_{L} when the load current is too high for a specific time interval. To perform this function, the microcontroller 2 may include an analog-to-digital converter. It is understood that the DEN and the IS terminal are optional; the diagnosis information can also be requested and transmitted via a digital communication link such as the SPI bus.

In the depicted example, the microcontroller 2 is supplied by a stabilized supply voltage V_{DD}. It is understood that the microcontroller 2 is just an example for a controller circuit. The microcontroller 2 may include a processor and memory for storing software instructions for the processor which can be executed by the processor to cause the microcontroller to perform the functions described herein. It is understood that other controllers may not (or only partly) rely on software instructions but have a hard-wired circuits.

A conventional fuse interrupts the current path between load and supply by melting at a certain point which happens when the fuse material carries a specific current for a specific time. To implement an electronic fuse, the microcontroller 2 may monitor the load current i_{L} (via the diagnosis mechanism described above) and trigger a switch-off of the transistor T_{L} (e.g. by outputting the signal S_{IN} with a low-level) dependent on the load current. The microcontroller 2 may be configured to calculate (based on the load current information) a value representing the electrical power, which potentially heats up the cable connecting the output terminal OUT of the smart switch 1 and the load Z_{LOAD}. A thermal model of the cable may be used trigger a switch-off. In FIG. 1 the current i_{GND} symbolized the smart switch’s own current consumption.

Using the concept discussed above with reference to FIG. 1, the protective function as such is implemented in the microcontroller. That is, the microcontroller determines when to trigger a switch-off of the transistor T_{L}. This gives the user of the circuit a maximum of flexibility because the algorithm that triggers the switch-off of the transistor T_{L} is under full control of the user who can program the microcontroller 2. However, it is obvious that such an approach may be error-prone, and in many application it is desired to have a protective function that is not dependent on software provided by the user.

According to another concept, the protective function is moved from the microcontroller 2 to the smart switch 1. However, this avoids the need for user-provided software but makes it complicated for the user to configure the protective function and to adapt it to the circuit/subsystem to be protected by the electronic fuse.

FIG. 2 illustrates a concept, according to which the protective function (i.e. the function determining when to trigger a switch-off due to an over-current) is implemented in the smart switch 1, while providing the user with a high flexibility to configure the protective function and adapt it to the circuit/subsystem to be protected by the electronic fuse. The electronic switch T_{L} connected between the terminals VS and OUT, the gate driver 11 and the current sensing circuit 12 are substantially the same as in the example of FIG. 1 and reference is made to the description above. Like in the example of FIG. 1 the control logic 10 provides the logic signal S_{ON} for the gate driver. The input signal S_{IN}, which indicates the desired state (on/off) of the electronic switch T_{L} is provided by a digital communication interface (e.g. and SPI). In one example, the signal S_{IN} is set to a High level in response to receiving a switch-on command via the communication interface and to a Low level in response to receiving a switch-off command. As mentioned above switch-on/off commands may be sent by a microcontroller or any other external controller device.

According to the example of FIG. 2, the smart switch 1 includes a squaring circuit 14 that is configured to receive a current sense signal i_{CS}, which represents the load current i_{L} passing through the electronic switch T_{L}, and to output – at a dedicated chip contact FILT – a current i₂ that represents the squared load current, i.e. i_{CS} = g⋅i_{CS}² = K⋅i_{L}² wherein g and K denote constant factors (gain or attenuation). The current sense signal i_{CS} may be provided by the current sensing circuit 12, which has been discussed above with reference to FIG. 1.

The chip contact FILT (chip terminal) allows the user to connect an external (i.e. outside the chip that includes the smart switch) filter circuit 3, wherein the current i₂ is drained (towards ground) by the filter circuit 3 thus causing a voltage V_{T} at the chip contact. The voltage V_{T} depends on the filter characteristics, which will be discussed in more detail later.

The smart switch 1 further includes a comparator circuit 15 that is configured to compare the voltage V_{T} present at the chip contact FILT with a reference voltage V_{REF}. The output of the comparator circuit 15 is coupled to the control logic 10, which is configured to cause a switch-off of the electronic switch T_{L} dependent on an output signal of the comparator circuit 15. In one embodiment, the reference voltage V_{REF} used by the comparator circuit 15 may be configurable (e.g. by an external controller via the digital communication interface) based on information received from the digital communication interface.

In essence, a switch-off of the electronic switch T_{L} is triggered when the voltage V_{T} reaches or exceeds the reference voltage V_{REF}. In the depicted example (FIG. 2) the reference voltage is provided by a controllable voltage source 16. Many different implementations of controllable voltage sources and comparator circuits are as such known and thus not further discussed herein in more detail.

In the example of FIG. 2, the filter circuit 3 is a first-order low-pass (RC filter) composed of a resistor R_{F} and a capacitor C_{F}, wherein the resistor R_{F} and the capacitor C_{F} are coupled in parallel between the terminal FILT and ground. In some embodiments, higher-order filters (e.g. cascaded RC filters) may be used. The concept explained herein allows the user to flexibly configure the characteristics of the electronic fuse by selecting the values for the resistor R_{F}, the capacitor C_{F} and (optionally) the reference voltage V_{REF}. The filter circuit 3 basically represents a thermal model, which transforms the electric power, which is represented by the squared load current i₂, into temperature information. Accordingly, the voltage V_{T} may be interpreted as a temperature value. In one embodiment, the voltage V_{T} represents a temperature of a wire that carries the load current i_{L} while the filter circuit 3 emulates the thermal behavior of the wire. In another embodiment, the voltage V_{T} represents a temperature of a more complex subsystem that drains the load current i_{L} while the filter circuit 3 emulates the thermal behavior of the subsystem.

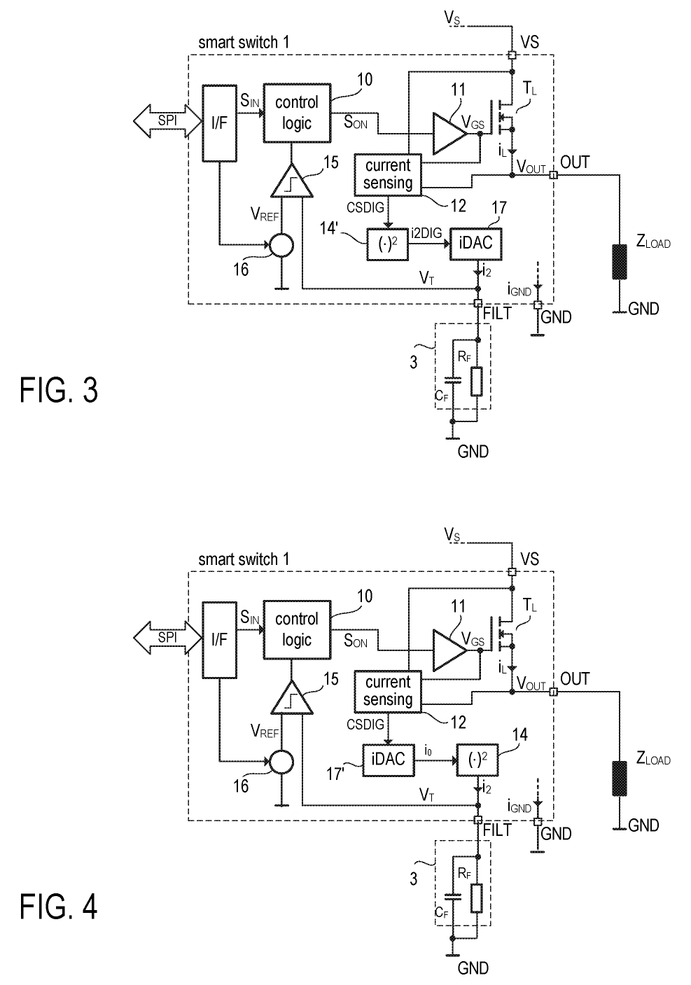

In the embodiment, the current sensing circuit 12 provides an analog current sense signal, and the squaring circuit 14 includes an analog multiplier. The exemplary embodiments of FIGS. 3 and 4 are modifications of the embodiment shown in FIG. 2, in which the current sensing circuit 12 provides a digital current sense signal CSDIG. Suitable current sensing circuit 12 circuits with digital output are as such known and thus not further discussed herein in more detail. For example, such current sensing circuits may include a sense transistor and a successive approximation register (SAR) analog-to-digital converter (ADC) to generate the digital current sense signal CSDIG.

In the embodiment of FIG. 3, the smart switch 1 includes a digital squaring circuit 14’ which is configured to square the digital current sense signal CSDIG. That is, the digital squaring circuit 14’ includes a multiplier which calculates the square CSDIG × CSDIG and provides the product as digital output signal i2DIG. To obtain the analog current i₂, which is output at the chip terminal FILT, the smart switch 1 includes a current output digital-to-analog converter 17. Except for the digital implementation of the current sensing and the squaring (and thus the additional digital-to-analog converter 17), the example of FIG. 3 is identical with the example of FIG. 2 and reference is made to the description above to avoid unnecessary reiterations.

In the embodiment of FIG. 4, the smart switch 1 includes a digital-to-analog converter 17’ which is configured to convert the digital current sense signal CSDIG into a corresponding analog signal i₀, which is an analog current signal in the depicted example. Therefore, an analog squaring circuit 14 can be used like in the example of FIG. 2. Accordingly, the squaring circuit 14 is configured to provide the analog current signal i₂, which is proportional to the square of the current i₀, i.e. i₂ = g⋅i₀², wherein g denotes a constant factor (gain or attenuation). Except for the digital implementation of the current sensing and the thus the additional digital-to-analog converter 17’, the example of FIG. 4 is identical with the example of FIG. 2 and reference is made to the description above to avoid unnecessary reiterations.

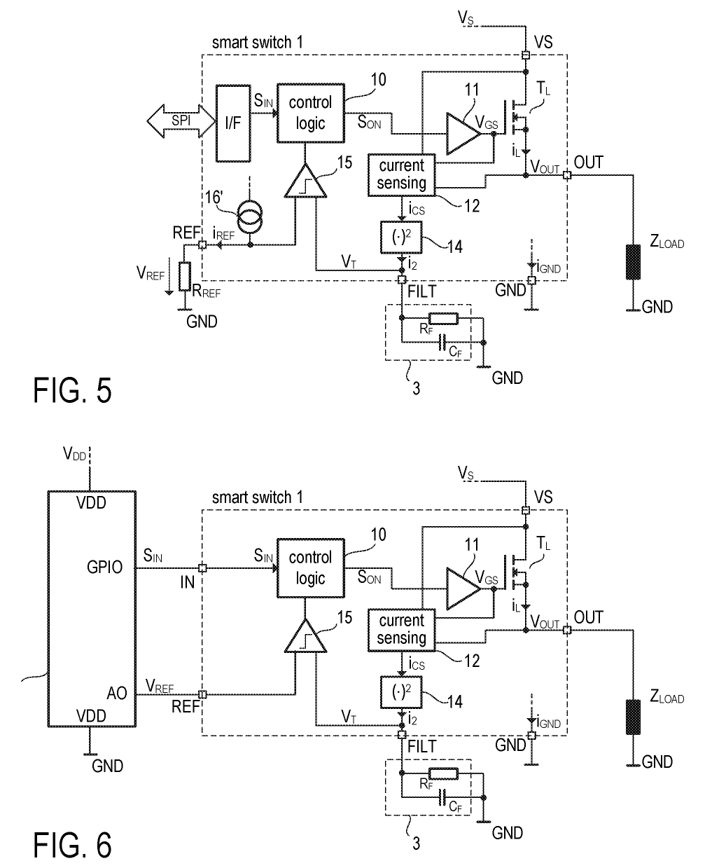

In the examples of FIG. 2-4, the reference voltage V_{REF} for the comparator 15 is set via the digital communication link (e.g. by an external controller). In the example of FIG. 5, the reference voltage V_{REF} depends on an external circuit component connected to a further chip terminal REF, in particular on a passive circuit component such as the resistor R_{REF}. To generate the reference voltage V_{REF} for the comparator 15, the smart switch 1 may include a current source 16’ (instead of the voltage source 16 shown in FIGS. 2-4), which is configured to output a reference current i_{REF} at the chip terminal REF. As can be seen from FIG. 5, the resulting voltage drop V_{REF} across the resistor R_{REF} is used as reference voltage by the comparator 15 (V_{REF} = R_{REF}⋅i_{REF}). The approach of FIG. 5 allows the user to set the filter characteristics of the filter 3 as well as the reference voltage V_{REF} by choosing suitable parameters (e.g. resistances and capacitance) of external passive circuit components. Except for the way how the reference voltage V_{REF} is provided to the comparator 15, the example of FIG. 5 is identical with the example of FIG. 2 and reference is made to the description above to avoid unnecessary reiterations.

FIG. 6 illustrates a further embodiment, which can also be regarded as a modification of the example of FIG. 2. According to FIG. 6, the reference voltage V_{REF} is generated by the external controller (e.g. microcontroller 2) and provided to the smart switch 1 at the chip terminal REF. The current source 16’ (see FIG. 5) is therefore not needed in the present example. If the analog output AO of the controller 2 is capable of sinking current, the current source 16’ does not need to be removed.

The example of FIG. 6 does not require a digital communication interface, because the input signal S_{IN} is generated by the controller 2 and output at a general purpose input/output (GPIO) pin of the controller, while the smart switch 1 receives the input signal S_{IN} at the input terminal IN (like in the example of FIG. 1). It is, however, understood that the present example does not exclude the additional use of a digital communication interface. Except for the way how the reference voltage V_{REF} is provided to the comparator 15 and the way the input signal S_{IN} is generated, the example of FIG. 6 is identical with the example of FIG. 2 and reference is made to the description above to avoid unnecessary reiterations.

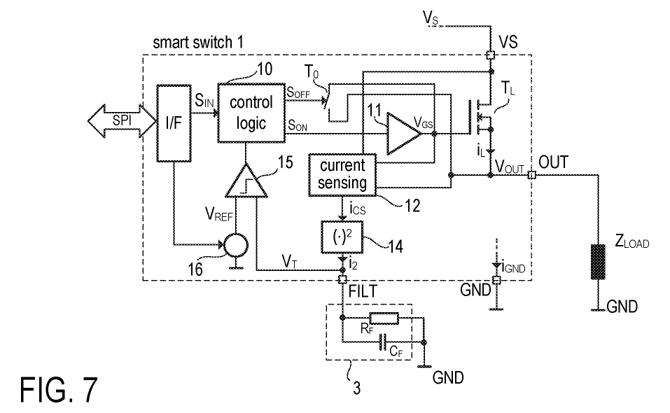

FIG. 7 illustrates a further embodiment, which can also be regarded as a modification of the example of FIG. 2. The only difference between FIG. 2 and 7 is the way how the power transistor T_{L} is switched-off in the event of an over-current (signaled by comparator 15). According to FIG. 7 a switch-off of the power transistor T_{L} is effected by switching on a further transistor T₀, which is connected between gate and source of the power transistor T_{L}. The control logic 10 activates (switches on) the transistor T₀ in response to the comparator 15 signaling an over-current. In the present example, the transistor T₀ is activated by the signal S_{OFF}. Upon activation, the transistor T₀ forces the gate-source voltage of the power transistor T_{L} to a value close to zero, thus discharging the gate of the power transistor and switching it off. The additional transistor T₀ can be regarded as a part of the control logic 10. Nevertheless, it is depicted as a separate element in the example of FIG. 7 to better illustrate its function.

The examples described herein are summarized below. It is understood that the following is not an exhaustive list of examples but rather an exemplary summary. Further examples can be obtained by combining different elements of the examples shown in FIG. 2-7 and discussed in detail above.

According to one example, a circuit includes an integrated circuit (IC) with a chip contact / terminal for connecting, during operation, a filter circuit. The IC further includes a driver configured to drive a power transistor in accordance with a logic signal; a squaring circuit configured to receive a current sense signal that represents a load current passing through the power transistor and to output, at the chip contact, a first current that represents the squared load current (see, e.g. FIG. 2-7, current i₂); a comparator circuit configured to compare a voltage present at the chip contact (see, e.g. FIG. 2-7, voltage V_{T}) with a reference voltage; and a control logic configured to generate the logic signal and to cause a switch-off of the power transistor dependent on an output signal of the comparator circuit.

The current sensing circuit may provide an analog or a digital current sense signal and the squaring may be accomplished either by an analog or a digital multiplier.

In some examples, the current sense signal received by the squaring circuit is an analog current signal and the squaring circuit includes an analog multiplier that is configured to square the analog current signal to generate the first current.

In some examples, the current sense signal received by the squaring circuit is a digital signal, wherein the squaring circuit includes a digital multiplier that is configured to square the digital signal and a digital-to-analog converter that is configured to generate the first current from a digital output signal of the digital multiplier (see, e.g. FIG. 3).

In some examples, the current sense signal received by the squaring circuit is a digital signal, wherein the squaring circuit includes a digital-to-analog converter that is configured to generate an analog sense current (see, e.g. FIG. 4, current i₀) from the digital signal and an analog multiplier that is configured to square the analog sense current to generate the first current.

In some examples, the IC includes a digital communication interface that is configured to communicate with an external controller (see FIGS. 2-5 and 7, interface labelled “I/F”).

In some examples, the reference voltage, which is used by the comparator circuit, is configurable based on information received from the digital communication interface. Alternatively, the reference voltage may be configurable based on a parameter of a passive external circuit component connected to a chip terminal of the IC (see, e.g. FIG. 5, terminal REF). According to a further alternative, the reference voltage is set by an external controller via a dedicated chip terminal (see FIG. 6, terminal REF).

The voltage present at the chip contact, to which the filter circuit is connected during operation, represents a temperature of a wire that carries the load current. The filter circuit may be a passive RC filter. It may be a first order low-pass filter or a higher-order filter.

In some examples, the circuit includes a controller that coupled to the IC. In some examples, the controller may be configured to configure the reference voltage used by the comparator circuit of the IC.

In some examples, the IC includes a digital communication interface, wherein the controller is configured to communicate with the integrated circuit via the digital communication interface. The digital communication interface may be a serial bus interface (e.g. a Serial Peripheral Interface, SPI).

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond – unless otherwise indicated – to any component or structure, which performs the specified function of the described component (e.g., that is functionally equivalent), even though not structurally equivalent to the disclosed structure, which performs the function in the herein illustrated exemplary implementations of the invention.

1. An circuit comprising:
an integrated circuit comprising a chip contact (FILT) for connecting, during operation, a filter circuit ,
wherein the integrated circuit further comprises:
a driver configured to drive a power transistor (T_{L}) in accordance with a logic signal (S_{ON});
a squaring circuit configured to receive a current sense signal (i_{CS} CS_{DIG}) that represents a load current (i_{L}) passing through the power transistor (T_{L}) and to output, at the chip contact (FILT), a first current (i₂) that represents the squared load current (i_{L});
a comparator circuit configured to compare a voltage (V_{T}) present at the chip contact (FILT) with a reference voltage (V_{REF}); and
a control logic configured to generate the logic signal (S_{ON}) and to cause a switch-off of the power transistor (T_{L}) dependent on an output signal of the comparator circuit.

2. The circuit of claim 1,
wherein the current sense signal received by the squaring circuit is an analog current signal (i_{CS}); and
wherein the squaring circuit includes an analog multiplier that is configured to square the analog current signal (i_{CS}) to generate the first current (i₂).

3. The circuit of claim 1,
wherein the current sense signal received by the squaring circuit is a digital signal (CSDIG); and
wherein the squaring circuit includes a digital multiplier that is configured to square the digital signal (CSDIG) and a digital-to-analog converter that is configured to generate the first current (i₂) from a digital output signal (i2DIG) of the digital multiplier.

4. The circuit of claim 1,
wherein the current sense signal received by the squaring circuit is a digital signal (CSDIG); and
wherein the squaring circuit includes a digital-to-analog converter that is configured to generate an analog sense current (i₀) from the digital signal (CSDIG) and an analog multiplier that is configured to square the analog sense current (i₀) to generate the first current (i₂).

5. The circuit of claims claim 1, further comprising:
a digital communication interface configured to communicate with an external controller.

6. The circuit of claim 5,
wherein the reference voltage (V_{REF}) is configurable based on information received from the digital communication interface.

7. The circuit of claim 1,
wherein the voltage (V_{T}) present at the chip contact (FILT) represents a temperature of a wire that carries the load current.

8. The circuit of claim 1,
wherein the filter circuit is a first-order low-pass comprising a resistor (R_{F}) and a capacitor (C_{F}), or a passive higher-order low-pass.

9. The circuit of claim 1,
wherein the integrated circuit further comprises a further chip contact (REF) for connecting, during operation, a passive circuit component (R_{REF}),
wherein the reference voltage (V_{REF}) depends on a parameter of the passive circuit component (R_{REF}).

10. The circuit of claim 9,
wherein the passive circuit component is a resistor (R_{REF}),
wherein the integrated circuit further comprises a current source configured to output a reference current (i_{REF}) at the further chip contact (REF), and
wherein the reference voltage (V_{REF}) depends on the resistance of the resistor (R_{REF}).

11. The circuit of claim 1, further comprising a controller coupled to the integrated circuit.

12. The circuit of claim 11,
wherein the controller is configured to configure the reference voltage (V_{REF}) used by the comparator circuit of the integrated circuit.

13. The circuit of claim 11,
wherein the integrated circuit includes a digital communication interface (I/F), and
wherein the controller is configured to communicate with the integrated circuit via the digital communication interface (I/F).

14. The circuit of claim 13,
wherein the digital communication interface (I/F) is a serial bus interface.
